(19) United States
(12) Patent Application Publication
(10) Pub. No.: US 2010/0283384 A1
(43) Pub. Date: Nov. 11, 2010

(54) OLED-ARRANGEMENT PROVIDED WITH AN ENCAPSULATING STRUCTURE

(75) Inventors: Herbert Lifka, Eindhoven (NL); Peter Van De Weijer, Eindhoven (NL); Margot Laura Van Grootel, Eindhoven (NL); Cristina Tanase, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/596,865

(22) PCT Filed: Apr. 24, 2008
(86) PCT No.: PCT/IB08/51583

§ 371 Date: Oct. 21, 2009

(30) Foreign Application Priority Data
Apr. 27, 2007 (EP) 07107149.2

(51) Int. Cl. H01J 1/63

(52) U.S. Cl. 313/504

(57) ABSTRACT

The present invention relates to an OLED-arrangement (1) provided with an encapsulating structure (2) for protecting an OLED-device (3). The OLED-arrangement (1) comprises an internally operative substance binding member (15) and the encapsulating structure (2) comprises a barrier (11) and a covering layer (5) formed by a polymeric material arranged outside the barrier (11). The barrier (11) is arranged outside the substance binding member (15). The present invention aims at providing a robust and reliable encapsulation of OLED-arrangements.

### TECHNICAL FIELD OF THE INVENTION

The present invention relates to an OLED-arrangement provided with an encapsulating structure for protecting an OLED-device.

### TECHNICAL BACKGROUND

Organic light-emitting diodes (OLEDs) are sensitive to mechanical stresses and they may easily be damaged by various ambient substances, such as water, moisture or oxygen. In order to provide OLEDs having a sufficient lifetime the OLED thus need to be protected from detrimental environmental conditions.

Protection of organic LEDs, including polymer based and small-molecule based, is sometimes performed with a glass or a metal lid sealed at the edges with glue. DE 102 34 162 A1 shows such a cover for protection of an OLED-arrangement from moisture and/or air. In order to remove water that penetrates through the edge seal, a drying agent is provided on the inside of the cover. Glass lids may be considered fragile and the creation of a cavity for the accommodation of the OLED may result costly.

Furthermore, it is realized that OLED-arrangements are exposed to a wide range of temperature conditions.

### OBJECTS OF THE INVENTION

It is an object of the present invention to provide an improved solution that alleviates the mentioned drawbacks with present OLED-arrangements. Furthermore, it is an object to provide a more cost-efficient protection of OLEDs. It is desirable to achieve a robust and reliable solution in accordance with the objects of the present invention and keep high standard as regards quality and functionality by providing an alternative protection of an OLED-arrangement.

Furthermore, it is desirable to obtain a solution which enables accurate performance under impact from various internal as well as external environmental factors, such as heat, moisture, light and UV-rays.

### SUMMARY OF THE INVENTION

According to the present invention, these and other objects are achieved through an OLED-arrangement provided with an encapsulating structure for protecting an OLED-device. The OLED-arrangement comprises an internally operative substance binding member and said encapsulating structure comprises a barrier and a covering layer formed by a polymeric material arranged outside said barrier and said barrier layer is arranged outside said substance binding member.

Hence, a robust encapsulating structure that can be produced in a cost-effective manner is provided. The encapsulating structure protects the OLED-arrangement from e.g. degradation by water and oxygen. Furthermore, it provides protection to the OLED-arrangement from damage due to mechanical impact.

The covering layer and the barrier layer are preferably transparent. Thus, light extraction through the encapsulating structure is provided.

Advantageously, the encapsulating structure further comprises an optical out coupling structure for light extraction. Thus, the refractive index of the out coupling structure may be configured for enabling enhanced out coupling of light from the OLED-arrangement. Hence, accurate light extraction through the encapsulating structure is achieved.

The optical out coupling structure preferably forms part of the covering layer. Thus, improved light extraction through the encapsulating structure is accomplishable. Furthermore, the out coupling structure can be formed in the same production step as the formation of the covering layer. Hence, a cost-effective encapsulating structure comprising an out coupling structure is enabled since the out coupling structure is integrated in the covering layer.

The covering layer may be provided with an uneven surface in order to improve light extraction.

More advantageously, the optical out coupling structure is formed by protrusions in the covering layer in order to improve the light extraction. Thus, the out coupling structure can be formed during the formation of the covering layer.

Preferably, the out coupling structure is formed by an array of protrusions. The protrusions typically range from 10 nm to 2 mm. Alternatively, the uneven surface is accomplished by recesses in relation to a protruding surface. The protrusions may be located on the side of the covering layer facing an ambient and/or on the side facing an OLED-device. The level of light extraction can be improved by adapting the number and location of protrusions.

An out coupling structure may also be accomplished by scattering particles and/or cavities that can be embedded in the covering layer for improvement of the optical out coupling. Particles such as e.g. TiO2, ZrO2 etc. usually have a rather high refractive index.

Advantageously, the covering layer is formed by a lid having a rim part and an elongated part. Thus, a space between the OLED-device and the elongated part of the lid can be provided. Hence, a getter can be mounted at a distance from the OLED-device to avoid contact between the getter and the cathode.

More advantageously, the covering layer is formed by a lid having a rim part, wherein said lid forms a cavity for accommodation of the OLED-device. Thus, the length of the rim part of the covering layer is adapted for accommodation of an OLED-device.

Preferably, the lid comprises at least one additional inner rim part forming a part of the lid. Thus, deflection of the lid is avoided since the inner rim supports the elongated part of the covering layer. Such deflection may result in contact between the getter and the cathode in case a getter is mounted on the inner side of the lid. By introducing inner rims deflection of the lid may be reduced or avoided and thus contact between the getter and the cathode may be avoided. Especially, for large-area devices, as intended for application of organic LEDs as a light source, additional rim(s) are preferred.

Preferably, the OLED-device is mounted on a rigid carrier being impermeable to an ambient substance and said encapsulating structure is mechanically connected to said rigid carrier to encapsulate said OLED-device. Thus a robust and reliable encapsulation of the OLED-device is provided. Such an ambient substance may for instance be water, moisture or oxygen.

The barrier is preferably formed by a film of an inorganic material. Thus an effective protection against moisture and/or oxygen is provided.

More preferably the barrier is formed by a multi-layer barrier in order to improve the barrier properties of the encapsulating structure. Thus, a barrier having a low pinhole density is accomplished.

The multi-layer barrier is preferably formed by inorganic films, such as films formed by silicon nitride or silicon oxide. Furthermore, an alternating stack of inorganic films and organic films can also be used.

The OLED-arrangement may comprise a second encapsulating structure in order to encapsulate both sides of a substrate supporting an OLED-device. Thus an encapsulating structure for substrates which may be permeable is provided. The second encapsulating structure thus prevent water and oxygen from penetrating the substrate.

The OLED-arrangement may be mounted on a flexible carrier. Furthermore, the barrier and covering layer may be flexible. Thus, an encapsulating structure for protection of a flexible OLED-device mounted on a flexible substrate is achieved.

### BRIEF DESCRIPTION OF THE DRAWINGS

The present invention will now be described in more detail with the reference to the accompanying schematic drawings, which show preferred embodiments in which:

FIG. 1 shows a section view of an OLED-arrangement provided with an encapsulating structure according to a first embodiment.

FIG. 2 shows a section view of an OLED-arrangement provided with an encapsulating structure according to a second embodiment.

FIG. 3 shows a section view of an OLED-arrangement provided with an encapsulating structure according to a third embodiment.

FIG. 4 shows a section view of an OLED-arrangement provided with an encapsulating structure according to a fourth embodiment.

### DETAILED DESCRIPTION OF EMBODIMENTS

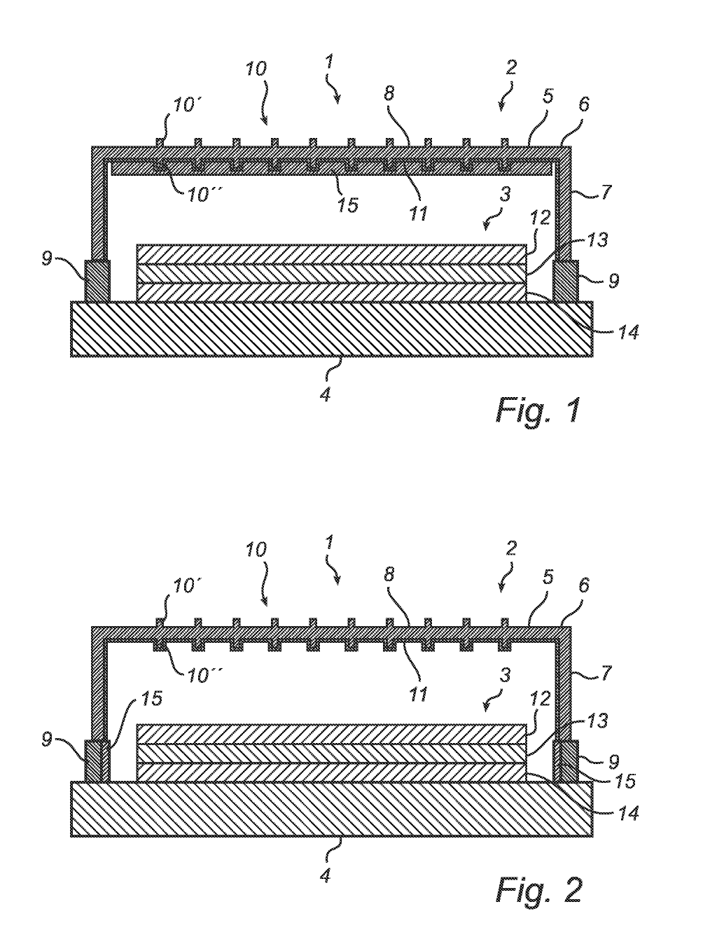

An OLED-arrangement 1 provided with an encapsulating structure 2 according to an embodiment of the present invention is shown in FIG. 1. The OLED-arrangement 1 comprises an OLED-device 3 mounted on a substrate 4, in this case a transparent substrate formed by glass. The encapsulating structure 2 comprises a covering layer 5 formed by a polymeric material, in this case a lid 6 having a rim part 7 and a elongated part 8. The elongated part 8 is substantially parallel to the substrate 4 supporting the OLED-device 3. The encapsulating structure 2 is connected to the substrate 4 using glue 9. The rim part 7, which is located around the active OLED-device area, is glued to the substrate 4 and thus a cavity for accommodation of the OLED-device 3 is provided. The rim part 7 provides a spacing between the substrate 4 and the elongated part 8. Thus, the elongated part 8 is spaced from the substrate 4 a certain distance in order to accommodate the OLED-device 3.

The covering layer 5 has an out coupling structure 10 in order to provide more efficient light extraction through the encapsulating structure 2. The out coupling structure 10 forms part of the plastic lid 6. The out coupling structure 10 is formed by protrusions 10′ on the outer side of the lid 6 and protrusions 10″ on the inner side of the lid 6. The lid 6 is formed by a polymeric material, such as higher plastics like PES or PEN. Higher plastics are preferred due to their higher glass transition temperature. The encapsulating structure 2 further comprises a barrier 11 on the inner side of the lid 6 in order to protect the organic device from degrading by water and oxygen from the ambient atmosphere. The barrier 11 may be formed by a thin film barrier of silicon nitride or by multiple layers of silicon nitride and/or silicon oxide. In this case the barrier 11 is formed by a multi-layer barrier formed by a stack of siliconnitride-siliconoxide-siliconnitride-siliconoxide-siliconnitride. The thickness of each layer depends on the optical out coupling optimization for the whole OLED stack in order to obtain maximum transmittance and efficiency. In one barrier the thickness of the multi-layers may be 200 nm, 100 nm, 100 nm, 100 nm and 100 nm respectively.

A stack of inorganic-organic layers can be used. More in detail such a stack may be formed of 200 nm siliconnitride-5 μm acrylate and 200 nm siliconnitride 5 μm acrylate and 200 nm siliconnitride.

The dual-side emissive OLED-device 3 is formed by a number of layers including a transparent cathode 12, an organic light emitting layer 13 and a transparent anode 14.

In order to avoid damage of the OLED-device 3 caused by water that penetrates through the encapsulating structure 2, a substance binding member 15, in this case a getter, is mounted inside relative the encapsulating structure 2. The getter 15 will absorb the small amounts of water that may diffuse through the few pinholes in the barrier layer 11 and the glue edge 9. A transparent getter 15 is glued to the barrier layer 11. It is desirable to avoid contact between the getter 15 and cathode 12 since such contact may damage the OLED-device 3. Such contact is avoided due to the spacing achieved by the rim part 7.

The OLED-arrangement 1 in this embodiment is dual-side emissive since the cathode 12 and the anode 14 are transparent. Thus, light is allowed to pass in both directions of the OLED-device 3. Since the encapsulating structure 2 and the substrate 4 supporting the OLED-device 3 are transparent, light is extracted through the substrate 4 and the encapsulating structure 2.

A second embodiment of the present invention is shown in FIG. 2. Essentially all features disclosed in the first embodiment are also present in the second embodiment with reference numerals identifying similar or same features. Having mentioned this the description will focus on explaining the differing features. The second embodiment differs in that the getter 15 is placed next to the glue 9 that connects the lid 6 to the substrate 4. The lid 6 with out coupling structure 10 is positioned at a distance from the OLED-device 3. Alternatively, the plastic lid 6 with out coupling structure 10 may in this embodiment be placed directly on top of, in contact with, the OLED-device 3 since no getter is attached to the barrier 11. Furthermore, a non-transparent getter can be used.

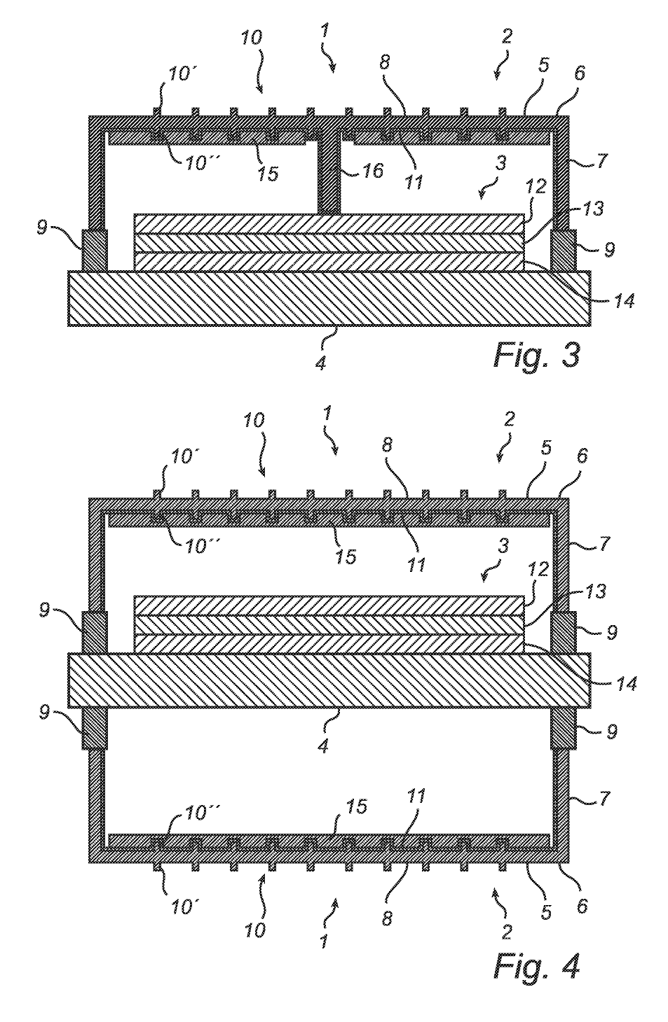

A third embodiment of the present invention is shown in FIG. 3. Essentially all features disclosed in the first embodiment are also present in the third embodiment with reference numerals identifying similar or same features. Having mentioned this the description will focus on explaining the differing features. In this embodiment the encapsulating structure 2 has an additional inner rim 16 forming a part of the plastic lid 6, see FIG. 3. Plastic lids may be flexible and may thus deflect. Especially, deflection of the lid may occur in a lid encapsulating large-area devices. As described it is desirable to avoid contact between the getter 15 and the cathode 12 since contact may damage the OLED-device 3. Such contact may be avoided due to the spacing achieved by the rim part 7. However, in large-area devices the getter 15 may contact the cathode 12 due to the flexibility of the plastic lid 6. Therefore, inner rim(s) 16 are preferred for encapsulation of large-area devices. The inner rim 16 only serve for supporting purposes and thus no glue is applied at the inner rim 16. The purpose of the inner rim(s) 16 is to prevent deflection of the lid 6. The barrier layer 11 deposited on the inner rim 16 may contact the OLED-device 3. However, the additional rim 16 will prevent contact between the getter 15 and the cathode 12. To avoid possible damage to the OLED-device caused by inner rims they should preferably contact a larger area to distribute the pressure.

A fourth embodiment of the present invention is shown in FIG. 4. Essentially all features disclosed in the first embodiment are also present in the fourth embodiment with reference numerals identifying similar or same features. Having mentioned this the description will focus on explaining the differing features. In this embodiment a dual-side emissive OLED-device 3 mounted on a flexible substrate 4′ is provided with two encapsulating structures 2. The flexible transparent substrate 4′ supporting the OLED-device 3 is in this case formed by polyimide. Since the intrinsic barrier of the polyimide substrate 4′ is not sufficient to protect the OLED-device 3 from water and oxygen in the ambient atmosphere, a second encapsulating structure 2 is glued to the substrate 4′ to protect the OLED-device 3.

In the following an exemplifying process of encapsulation of an OLED-arrangement 1 using an encapsulating structure 2 according to the present invention is described. The covering layer 5 may be fabricated using a mould-injection process. Mould-injection is preferred when considering large-scale production of encapsulating structures 2. Furthermore, an out coupling structure 10 forming a part of the covering layer 5 may easily be formed in the mould-injection process. Other methods such as embossing or stamping may however be suitable. In case the covering layer 5 is formed using a stamp, an out coupling structure 10 can be formed during formation of the covering layer 5 by adapting the surface of the stamp.

Degradation by water and oxygen may damage and/or shorten the specified lifetime of an OLED-device 3. By deposition of a thin film barrier of silicon nitride or a stack of silicon nitride and silicon oxide on the inner side of the plastic lid 6, the barrier properties will improve in a large extent. The film barrier may be deposited by plasma enhanced chemical vapor deposition. After deposition of the barrier 11 glue is dispensed on the rim part 7 in air under yellow lighting conditions. Then the lid 6 is transferred into a nitrogen atmosphere where the getter 15 is glued in the lid 6. The lid 6 is then pressed on the substrate 4 on which the OLED-device 3 is mounted. The glue 9 is pre-cured with UV light. Final curing is performed in a furnace.

It will be appreciated that the described embodiment of the invention can be modified and varied by a person skilled in the art without departing from the inventive concept defined in the claims. It is realized by a person skilled in the art that features from various embodiments disclosed herein may be combined with one another in order to provide further alternative embodiments.

In the described embodiments encapsulation of dual-side emissive OLED-devices are disclosed. However, other types of devices, such as top emitting OLED-devices and bottom emitting OLED-devices, may be encapsulated using an encapsulating structure according to an embodiment of the present invention. It is realized from the application that such structures can be used for all kind of OLED devices ranging from OLED lamps to OLED displays of any type.

A “substance binding member” is a structure comprising a material which is capable of binding a substance by any mechanism, chemical or physical, including absorption. Included among substance binding members are so-called “getters”. The substance binding member may be composed of one or several different materials, which each may be selected to bind a particular substance. For example, these materials may have voids or open spaces close to the molecular diameter of the substances to be bound, such as H₂O, CO₂, O₂ or N₂O. Examples of such materials include sintered alumina gel alumina-silicate gel and silica gel. Furthermore, calcium oxide may be used as a material for binding, by adsorption, CO₂ and H₂O and phosphoric anhydride may be used to bind H₂O.

1. An OLED-arrangement including an encapsulating structure for protecting an OLED-device, said OLED-arrangement comprising an internally operative substance binding member (15), said encapsulating structure comprising a barrier and a covering layer comprising a polymeric material arranged outside said barrier said, barrier being arranged outside said substance binding member, said covering layer comprising a lid having a rim portion and an elongated portion, said covering layer and said barrier being optically transparent, said encapsulating structure further comprising an optical out coupling structure for light extraction.

2-3. (canceled)

4. The OLED-arrangement according to claim 3, wherein said optical out coupling structure form part of the covering layer.

5. The OLED-arrangement according to claim 3, wherein said covering layer has an uneven surface.

6. The OLED-arrangement according to claim 3, wherein said optical out coupling structure is formed by protrusions in the covering layer.

7. The OLED-arrangement according to claim 3, wherein said optical out coupling structure is formed by scattering particles embedded in the covering layer (5).

8. The OLED-arrangement according to claim 3, wherein said optical out coupling structure is formed by cavities in the covering layer.

9. (canceled)

10. The OLED-arrangement (1) according to claim 1, wherein said covering layer (5) is formed by a lid (6) having a rim part (7), wherein said lid (6) forms a cavity where the OLED-device (3) is accommodated.

11. (canceled)

12. The OLED-arrangement (1) according to claim 1, wherein said OLED-device is mounted on a rigid carrier being impermeable to an ambient substance and said encapsulating structure is mechanically connected to said rigid carrier to encapsulate said OLED-device.

13. The OLED-arrangement according to claim 1, wherein said barrier is formed by a film of an inorganic material.

14. The OLED-arrangement according to claim 1, wherein said barrier is formed by a multi-layer barrier.

15. The OLED-arrangement according to claim 14, wherein said multi-layer barrier is formed by inorganic films.

16. The OLED-arrangement according to claim 14, wherein said multi-layer barrier is formed by inorganic and organic films.

17. (canceled)
